(19) United States
(12) Patent Application Publication
(10) Pub. No.: US 2026/0060066 A1
(43) Pub. Date: Feb. 26, 2026

(54) SEMICONDUCTOR DEVICE AND METHOD FOR MANUFACTURING THE SAME

(71) Applicant: SK hynix Inc., Gyeonggi-do (KR)

(72) Inventors: Beom Ho MUN, Gyeonggi-do (KR); Ju Min LEE, Gyeonggi-do (KR); Jin Yul LEE, Gyeonggi-do (KR); Hong Seuk LEE, Gyeonggi-do (KR); Jung Hun JANG, Gyeonggi-do (KR)

(21) Appl. No.: 19/309,639

(22) Filed: Aug. 26, 2025

(30) Foreign Application Priority Data
Aug. 26, 2024 (KR) 10-2024-0114380

(51) Int. Cl. H01L 23/528; H01L 23/522; H01L 23/532; H10B 12/00

(52) U.S. Cl. CPC H01L 23/5283; H01L 23/5222; H01L 23/528; H01L 23/53271; H01L 23/5329; H10B 12/482; H10B 12/0335; H10B 12/315; H10B 12/34

(57) ABSTRACT

A semiconductor device including a tapered spacer and method for manufacturing the same are disclosed. The semiconductor device includes a conductive-line contact plug and a conductive pattern spaced apart from each other in a first direction; a conductive line disposed over the conductive-line contact plug and extending in a second direction perpendicular to the first direction; and a spacer structure configured to contact sidewalls of the conductive line and the conductive-line contact plug, and configured such that a width of an upper portion of the spacer structure is narrower than a width of a lower portion of the spacer structure.

### CROSS-REFERENCE TO RELATED APPLICATION

This patent document claims the priority and benefits of Korean patent application No. 10-2024-0114380, filed on Aug. 26, 2024, the disclosure of which is incorporated herein by reference in its entirety.

### TECHNICAL FIELD

The technology and embodiments of the present disclosure generally relate to a semiconductor device and a method for manufacturing the same, and more particularly to a semiconductor device including a tapered spacer, and method for manufacturing the same.

### BACKGROUND

As the degree of integration of semiconductor devices increases, the difficulty in designing integrated circuits (ICs) is developing exponentially.

During the development of semiconductor devices, the number of devices included per unit chip area is rapidly increasing while the size of each device is being gradually reduced, and this high degree of integration in semiconductor devices results in an increase in the complexity of integrated circuit (IC) processing and IC fabrication.

A plurality of conductive pattern structures and conductive lines may be arranged within an insulation layer included in a semiconductor device. Reduction of the spacing between the plurality of conductive pattern structures and the conductive lines may increase leakage current and cause interference between the conductive pattern structures and the conductive lines.

### SUMMARY

Various embodiments of the present disclosure relate to a semiconductor device capable of readily forming one or more conductive patterns by improving a spacer structure which is adjacent to one or more conductive lines.

In accordance with an embodiment of the present disclosure, a semiconductor device may include a conductive-line contact plug and a conductive pattern spaced apart from each other in a first direction; a conductive line disposed over the conductive-line contact plug and extending in a second direction perpendicular to the first direction; and a spacer structure configured to contact sidewalls of the conductive line and the conductive-line contact plug, and configured such that a width of an upper portion of the spacer structure is narrower than a width of a lower portion of the spacer structure.

In some embodiments of the present disclosure, the spacer structure may include a first spacer configured to contact the sidewalls of the conductive line and the conductive-line contact plug; a second spacer configured to contact the first spacer and configured such that a width of an upper portion of the second spacer is narrower than a width of a lower portion of the second spacer; and a third spacer disposed between the second spacer and the conductive pattern.

In some embodiments, the first spacer may include a material having a lower permittivity (lower-K) than silicon nitride.

In some embodiments, the first spacer may include silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof.

In some embodiments, the second spacer may include silicon oxide.

In some embodiments, the silicon oxide may be doped with one of nitrogen or fluorine.

In some embodiments, the third spacer may include silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof.

In some embodiments, the conductive pattern may be configured such that a width of a lower portion of the conductive pattern is narrower than a width of an upper portion of the conductive pattern.

In some embodiments, the semiconductor device may further include a memory element disposed on the conductive pattern.

In some embodiments, the conductive pattern may include a lower plug including polysilicon; an ohmic contact layer disposed on the lower plug and including metal silicide; and an upper plug disposed on the ohmic contact layer and including a metal material.

In some embodiments, the semiconductor device may further include a first impurity region and a second impurity region that are formed in a substrate, wherein the conductive-line contact plug is connected to the first impurity region.

In some embodiments, the conductive pattern may be connected to the second impurity region.

In some embodiments, the first impurity region may be disposed between two adjacent buried word lines.

In some embodiments, the conductive line may be a bit line; and the conductive pattern is a storage-node contact plug.

In accordance with another embodiment of the present disclosure, a semiconductor device may include a plurality of conductive lines spaced apart from each other on a substrate; a plurality of conductive-line contact plugs disposed below the conductive lines, respectively; a plurality of conductive patterns disposed between the conductive lines; and a plurality of spacer structures disposed between the conductive patterns and the conductive lines. Each of the spacer structures may include a first spacer configured to contact sidewalls of the conductive line and the conductive-line contact plug; a second spacer configured to contact the first spacer and configured such that a width of an upper portion of the second spacer is narrower than a width of a lower portion of the second spacer; and a third spacer disposed between the second spacer and the conductive patterns.

In some embodiments, the semiconductor device may further include a plug isolation layer disposed between the conductive patterns, wherein the conductive patterns and the plug isolation layer are alternately arranged in a direction in which the conductive lines extend.

In some embodiments, the plug isolation layer may include an insulation material.

In some embodiments, the first spacer may include a material having a lower permittivity (lower-K) than silicon nitride.

In some embodiments, the first spacer may include silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof.

In some embodiments, the second spacer may include silicon oxide.

In some embodiments, the silicon oxide may be doped with any one of nitrogen or fluorine.

In some embodiments, the third spacer may include silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof.

It is to be understood that both the foregoing general description and the following detailed description of the present disclosure are illustrative and are intended to provide further description of the embodiments on the present disclosure as claimed.

### BRIEF DESCRIPTION OF THE DRAWINGS

The above and other features and beneficial aspects of the embodiments of the present disclosure will become readily apparent with reference to the following detailed description when considered in conjunction with the accompanying drawings.

FIG. 1 is a plan view illustrating a semiconductor device according to some embodiments of the present disclosure.

FIG. 2 is a cross-sectional view illustrating the semiconductor device taken along the line A-A′ of FIG. 1 according to some embodiments of the present disclosure.

FIG. 3 is a cross-sectional view illustrating the semiconductor device taken along the line B-B′ of FIG. 1 according to some embodiments of the present disclosure.

FIGS. 4 to 16 are cross-sectional views illustrating methods for manufacturing the semiconductor device according to some embodiments of the present disclosure.

### DETAILED DESCRIPTION

The present disclosure provides embodiments and examples of a semiconductor device including a tapered spacer and method for manufacturing the same that may be used in configurations to substantially address one or more technical or engineering issues and to mitigate limitations or disadvantages encountered in some other semiconductor devices. Some embodiments of the present disclosure relate to a semiconductor device capable of easily forming one or more conductive patterns by improving a tapered spacer structure adjacent to one or more conductive lines. In recognition of the issues above, the semiconductor device according to some embodiments of the present disclosure may utilize tapered spacers between the conductive lines and the conductive patterns in order to facilitate the formation of such conductive patterns. In the semiconductor device, a first spacer directly contacting sidewalls of the conductive line does not include nitride, thereby preventing nitridation of the conductive line. In the semiconductor device, the first spacer includes a low-permittivity (low-K) material, and a second spacer including a tapered silicon oxide layer is formed on the first spacer, thereby improving parasitic capacitance between the conductive line and the conductive pattern.

Reference will now be made to the embodiments of the present disclosure in conjunction with the accompanying drawings. Wherever possible, the same reference numbers will be used throughout the drawings to refer to the same or like parts. While the embodiments of the present disclosure are susceptible to various modifications and alternative forms, specific embodiments thereof are shown by way of example in the drawings. However, the embodiments should not be construed as being limited to the embodiments set forth herein.

Hereinafter, various embodiments will be described with reference to the accompanying drawings. However, it should be understood that the embodiments are not limited to specific embodiments, but include various modifications, equivalents and/or alternatives of the embodiments. The embodiments of the present disclosure may provide a variety of advantageous effects capable of being directly or indirectly recognized.

The drawings may not be necessarily drawn to scale, and in some examples, proportions of at least some of structures in the drawings may be exaggerated to clearly show features of the embodiments. When a multilayer structure having two or more layers is disclosed in the drawings or detailed description, the relative positional relationship or arrangement order of the layers reflects a specific embodiment only and the scope or spirit of the present disclosure is not limited thereto, and it should be noted that the relative positional relationship or arrangement order of the layers may also be changed as necessary. In addition, the drawings or detailed descriptions of a multilayer structure may not reflect all layers present in a particular multilayer structure (e.g., one or more additional layers may be present between two illustrated layers). As a specific example, when a first layer in the multilayer structure is referred to as being “on” or “over” a second layer or “on” or “over” a substrate, the first layer may be directly formed on the second layer or the substrate but may also represent a structure where one or more other layers are present between the first layer and the second layer or between the first layer and the substrate.

Hereinafter, a semiconductor device and a method for manufacturing the same according to some embodiments of the present disclosure will be described in detail with reference to the attached drawings.

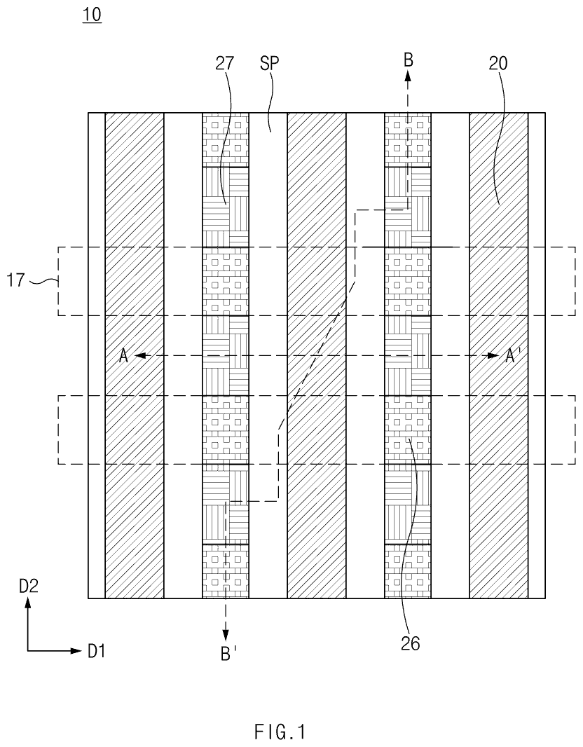

FIG. 1 is a plan view illustrating an example of a semiconductor device according to some embodiments of the present disclosure.

Referring to FIG. 1, the semiconductor device 10 may include at least one buried word line 17, at least one conductive line 20, at least one spacer structure (SP), at least one plug isolation layer 26, and at least one conductive pattern 27. FIG. 1 illustrates the positional relationship between the buried word lines 17, the conductive lines 20, the spacer structures (SP), the plug isolation layers 26, and the conductive patterns 27.

The semiconductor device 10 may include a plurality of memory cells. Each memory cell may include a cell transistor including a buried word line 17, a conductive line 20, and a memory element.

The buried word line 17 may operate as a gate of a cell transistor, may be disposed below the conductive line 20, and may extend in a first direction (D1) perpendicular to a second direction (D2) in which the conductive line 20 extends. In some embodiments, the buried word line 17 and the conductive line 20 may be disposed in the same semiconductor substrate, and the buried word line 17 may be disposed below the conductive line 20 with respect to one surface of the semiconductor substrate.

The conductive line 20 may include a metal material, and the conductive line 20 may be located between the spacer structure (SP) and the conductive patterns 27 or may be located between the spacer structure (SP) and the plug isolation layer 26.

In some embodiments, the conductive line 20 may be a bit line of the semiconductor device.

The spacer structure (SP) may extend in the same direction (D2) as the conductive line 20, and may include an insulation material.

The plug isolation layer 26 may be formed between adjacent conductive lines 20, and the conductive patterns 27 may be isolated from each other by the plug isolation layer 26. The plug isolation layer 26 and the conductive pattern 27 may be alternately arranged in the second direction (D2) in which the conductive lines 20 extend. In some embodiments, the conductive pattern 27 may be a storage-node contact plug.

The conductive pattern 27 may electrically interconnect an impurity region and a memory element that are arranged in a semiconductor substrate. The conductive pattern 27 may include a plurality of conductive material layers. Referring to FIG. 1, the conductive patterns 27 and the conductive lines 20 may be arranged in a spaced apart alternating configuration along the first direction D1 with the spacer structures SP filling the spaces between adjacent pairs of the conductive patterns 27 and the conductive lines 20. A single spacer structure SP may fill each such space between adjacent pairs of the conductive patterns 27 and the conductive lines 20.

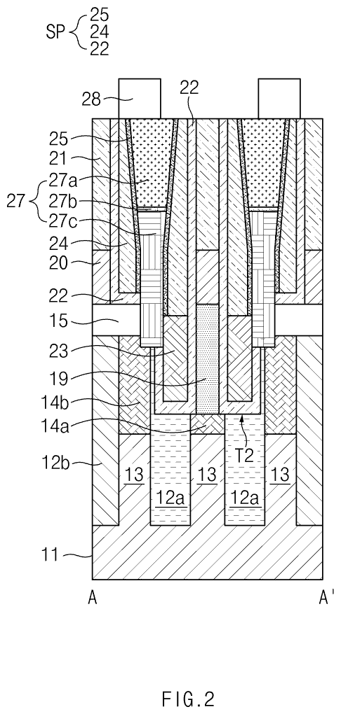

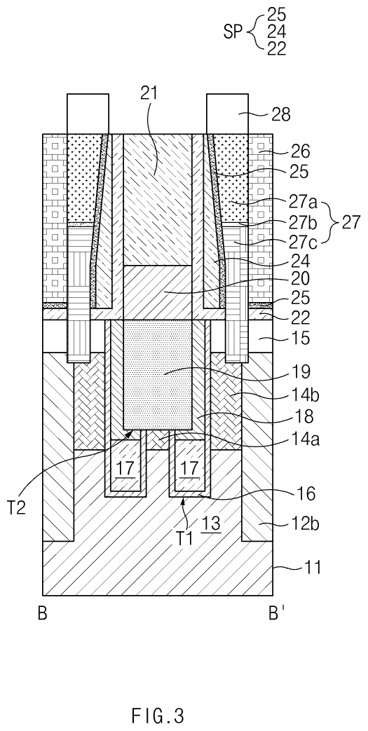

FIG. 2 is a cross-sectional view illustrating the semiconductor device taken along the line A-A′ of FIG. 1 according to some embodiments of the present disclosure. FIG. 3 is a cross-sectional view illustrating the semiconductor device taken along the line B-B′ of FIG. 1 according to some embodiments of the present disclosure.

Hereinafter, the structure of the semiconductor device 10 will be described in detail with reference to FIGS. 1 to 3.

The semiconductor device 10 may include a substrate 11.

The substrate 11 may be any material that is suitable for semiconductor processing. For example, the substrate 11 may include silicon, but may not be limited to silicon. The substrate 11 may also include other semiconductor materials such as germanium. The substrate 11 may include a group III/V semiconductor substrate, for example, a compound semiconductor substrate such as GaAs (Gallium Arsenide). The substrate 11 may include a silicon-on-insulator (SOI) substrate.

In some embodiments, the substrate 11 may include silicon, monocrystalline silicon, polysilicon, amorphous silicon, silicon germanium, monocrystalline silicon germanium, polycrystalline silicon germanium, carbon-doped silicon, a combination thereof, or a multilayer thereof.

At least one active region 13, at least one first device isolation layer 12a, and at least one second device isolation layer 12b may be formed within the substrate 11.

The active regions 13 may be defined by the first and second device isolation layers 12a and 12b. The device isolation layers (12a, 12b) may be formed by a shallow trench isolation (STI) process and may include an insulation material.

A first impurity region 14a and a second impurity region 14b may be formed on the active regions 13.

The first impurity region 14a and the second impurity region 14b may operate as source/drain regions of the cell transistor. Each of the first and second impurity regions 14a and 14b may include N-type impurities such as arsenic (As) or phosphorus (P).

Referring to FIG. 3, a first trench (T1) may be formed in the substrate 11. A gate insulation layer 16, a buried word line 17, and a gate capping layer 18 may be formed in the first trench (T1).

The gate insulation layer 16 may be formed conformally along the bottom surface and sidewalls of each of the first trenches (T1). The buried word line 17 may be formed on the gate insulation layer 16 to fill a lower portion of the first trench (T1).

The gate capping layer 18 may be formed on the top surface of the buried word line 17. In some embodiments, side surface of the gate capping layer 18 may be covered with the gate insulating layer 16, but in other embodiments the gate capping layer 18 may be on the gate insulating layer 16 covering the upper sidewalls of the first trench (T1) to fill the upper portion of the first trench (T1). The first trench (T1) may also be referred to as a gate trench. For example, the gate insulation layer 16 may include a high-permittivity (high-K) material, an oxide material, a nitride material, an oxynitride material, or a combination thereof. The gate capping layer 18 may include, for example, silicon oxide, silicon nitride, or a combination thereof.

The buried word line 17 may include a low-resistance metal material. The buried word line may include at least one of titanium nitride, tungsten, and molybdenum. According to an embodiment, the buried word line 17 may be formed by stacking titanium nitride and tungsten. According to another embodiment, the buried word line 17 may be formed of only titanium nitride. The buried word line 17 may operate as a gate of the cell transistor. The buried word line 17 may be referred to as a buried gate electrode.

The hard mask layer 15 may be used as an etching barrier for forming the first trench (T1), and a part or region of the hard mask layer may remain after the formation of the first trench (T1) and may be referred to as a remaining region of the hard mask layer 15. The hard mask layer 15 may be patterned by a mask pattern. The hard mask layer 15 may include, for example, silicon oxide. Also, for example, the hard mask layer 15 may include Tetra-Ethyl-Ortho-Silicate (TEOS).

A conductive-line contact plug 19 may be formed within the substrate 11. The conductive-line contact plug 19 may be connected to the first impurity region 14a, and may be formed within a contact hole (T2).

The contact hole (T2) may be a region in which the conductive-line contact plug 19 configured to connect the conductive line 20 to the first impurity region 14a is formed. The contact hole (T2) may be formed by etching the hard mask layer 15.

The first impurity region 14a may be exposed by the contact hole (T2). In some embodiments, the conductive-line contact plug 19 may include a conductive material such as polysilicon or a metal material.

Referring to FIG. 2, the conductive-line contact plug 19 viewed from a direction parallel to the second direction (D2) may have a narrower width than the contact hole (T2).

A conductive line 20 may be formed on the conductive-line contact plug 19. Then a conductive-line hard mask 21 may be formed on the conductive line 20. A stacked structure of the conductive-line contact plug 19, the conductive line 20, and the conductive-line hard mask 21 may be referred to as a conductive line structure.

The conductive line 20 may have a line shape extending in the second direction (D2). The conductive line 20 may include a conductive material such as a metal. The conductive-line hard mask 21 may include an insulation material.

The spacer structure (SP) formed along both sidewalls of the conductive line 20 may include a plurality of layers.

More specifically, the spacer structure (SP) may include a first spacer 22, a second spacer 24, and a third spacer 25.

The spacer structure (SP) may electrically isolate the conductive line 20 from the adjacent conductive pattern 27.

The first spacer 22 may be arranged along the side surfaces of the conductive-line contact plug 19, the conductive line 20, and the conductive-line hard mask 21, and may surround the bottom surface and the side surfaces of a gap-fill spacer 23. The first spacer 22 may include a material having a permittivity similar to or higher than the second spacer 24.

The first spacer 22 may be made or include a material having lower permittivity (lower-K) than silicon nitride for reducing parasitic capacitance between the conductive line structure and the conductive pattern.

In some embodiments, the first spacer 22 may include impurities. For example, the first spacer 22 may include carbon as impurities. For example, the first spacer 22 may include silicon oxycarbide (SiCO).

According to some embodiments, the first spacer 22 may include silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof. The materials included in the first spacer 22 may have a lower permittivity (lower-K) than silicon nitride so that the parasitic capacitance between the conductive line structure and the conductive pattern 27 may be reduced. Importantly, reducing the parasitic capacitance may improve the sensing margin of the semiconductor device.

In addition, according to some embodiments of the present disclosure, the first spacer 22 contacting the sidewalls of the conductive line structure may not include silicon nitride.

Since the first spacer 22 does not include silicon nitride, nitridation of a metal material (e.g., tungsten) included in the conductive line 20 may be prevented.

For example, the gap-fill spacer 23 may be a layer including silicon nitride, and may have a higher permittivity (dielectric constant) than the first spacer 22. The gap-fill spacer 23 may be a layer that gap-fills a region having no conductive-line contact plug 10 within the contact hole. The gap-fill spacer 23 may be an insulation plug. The first spacer 22 may be disposed to surround the bottom surface and the side surfaces of the gap-fill spacer 23.

The second spacer 24 may be disposed on the first spacer 22. The first spacer 22 may contact the bottom surface and the side surfaces of the second spacer 24.

The second spacer 24 may have a tapered shape having a narrower width at an upper portion thereof than a width of a lower portion thereof. The second spacer 24 may have a shape extending from the conductive-line hard mask layer 21 toward the conductive line 20. In addition, a width of the region of the second spacer 24 that is adjacent to the conductive-line hard mask layer 21 may be narrower than a width of the region adjacent to the conductive line 20.

The second spacer 24 may include silicon oxide. For example, the second spacer 24 may include silicon oxide doped with nitrogen, silicon oxide doped with fluorine, or silicon oxide doped with nitrogen and fluorine.

Since the second spacer 24 has a tapered shape, the process of forming the conductive pattern 27 may be facilitated. In addition, since the second spacer 24 has a tapered shape, a thickness of a dielectric material (e.g., silicon oxide and low-K material) layer disposed between the conductive line 20 and the conductive pattern 27 may increase which in turn may decrease the parasitic capacitance of the conductive line 20.

The third spacer 25 may be disposed on the second spacer 24, and may have an oblique shape along the side surface of the second spacer 24.

In some embodiments, the third spacer 25 may include silicon nitride or a material having a lower permittivity (lower-K) than silicon nitride. The material included in the third spacer 25 may include, for example, silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof.

A material having a lower permittivity (lower-K) than silicon nitride may hereinafter be referred to as a low-K material. In some embodiments, the spacer structure (SP) may have a KOK stack structure (Low-K-Oxide-Low-K) or a KON stack structure (Low-K-Oxide-Nitride).

According to some embodiments, before forming the first spacer 22 to contact the sidewall of the conductive line 20, a seed nitride layer may be formed on the sidewalls of the conductive line 20 and the conductive-line hard mask 21. Then the first spacer 22 may be formed on the seed nitride layer.

Forming the seed nitride layer, allows to maintain constant thickness of the first spacer 22 formed across the sidewalls of the conductive line 20 and the conductive-line hard mask 21. At this time, since the second spacer 24 is formed in a tapered shape on the first spacer 22, a subsequent process of forming the conductive pattern can be facilitated.

When a deposition process of a material having a lower permittivity (lower-K) than silicon nitride such as SiCO is performed on a target object, an overhang phenomenon may occur due to a difference in deposition speed between the top surface and the side surfaces of the target object.

More specifically, when the seed nitride layer is not formed, a difference in deposition speed between the conductive line and the conductive-line hard mask may occur during the deposition process of a material having a lower permittivity (lower-K) than silicon nitride (e.g., SiCO), such that the overhang phenomenon may occur.

According to some embodiments of the present disclosure, the spacer structure SP may include the first spacer 22 including a material having a lower permittivity (lower-K) than silicon nitride, and the second spacer 24 including silicon oxide, so that occurrence of an overhang for the conductive line 20 may be prevented.

The third spacer 25 may include a material having etch selectivity with respect to the second spacer 24. For example, in some embodiments the second spacer 24 may include silicon oxide and the third spacer 25 may include silicon nitride.

Referring to FIGS. 1 and 3, a plug isolation layer 26 may be formed on the third spacer 25. The plug isolation layer 26 may be formed between conductive line structures adjacent in the first direction (D1).

The plug isolation layer 26 may be formed between conductive patterns 27 adjacent to each other in the second direction (D2).

The plug isolation layer 26 and the conductive patterns 27 may be alternately disposed between adjacent conductive line structures in the first direction (D1).

The plug isolation layer 26 may include silicon nitride or a material having a lower permittivity (lower-K) than silicon nitride.

The conductive pattern 27 may be disposed between adjacent conductive line structures. The conductive pattern 27 may include an upper plug 27a, an ohmic contact layer 27b, and a lower plug 27c.

The upper plug 27a may include a conductive material such as a metal material. The ohmic contact layer 27b may include, for example, a metal silicide. The lower plug 27c may include, for example, a conductive material such as polysilicon.

The conductive pattern 27 may have a reverse tapered shape with a wider width of the upper portion of the conductive pattern 27 than a width of the lower portion of the conductive pattern 27.

Forming the spacer structure (SP) to have a tapered shape, allows forming the conductive pattern 27 between the spacer structures (SP) to have a reverse tapered shape which secures an upper area of the conductive pattern 27 for arranging the memory element 28.

In addition, the spacing (distance) between the lower plug 27c of the conductive pattern 27 and the conductive line is secured, resulting in reduction in parasitic capacitance. That is, the spacing (distance) between the lower plug 27c and the conductive line is intentionally maintained or controlled to have an adequate width to ensure significant reduction and or total prevention of parasitic capacitance and thus improved electrical performance of the device.

The memory element 28 may include, for example, a capacitor including a storage node. The storage node may have a cylinder shape or a pillar shape, and may be formed by a combination of the cylinder shape and the pillar shape according to an embodiment. In addition, the capacitor including the storage node may further include a dielectric layer and a plate node.

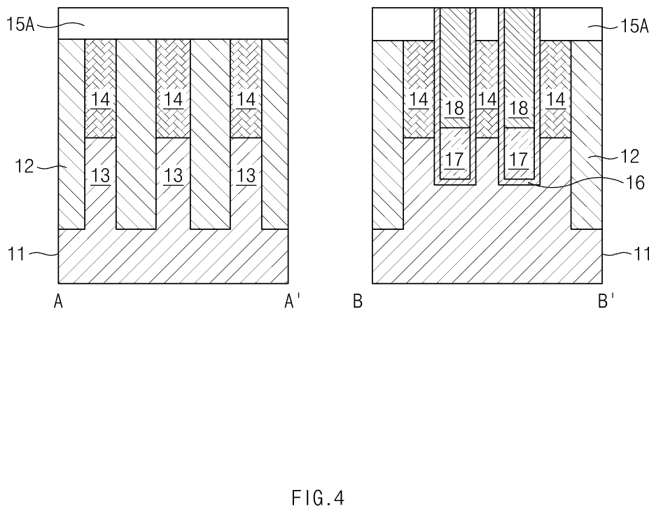

FIGS. 4 to 16 are cross-sectional views illustrating methods for manufacturing the semiconductor device according to some embodiments of the present disclosure.

FIGS. 4 to 16 are cross-sectional views illustrating the semiconductor device taken along lines A-A′ and B-B′ of FIG. 1.

Referring to FIG. 4, a device isolation layer 12 may be formed on a substrate 11. A plurality of active regions 13 may be defined by the device isolation layer 12.

The device isolation layer 12 may be formed by the STI (shallow trench isolation) process. The device isolation layer 12 may be formed by etching at least a portion of the substrate 11 to form a trench and filling the trench formed through such etching with an insulation material such as, for example, silicon oxide, silicon nitride, or a combination thereof.

The buried word line structure formed in the substrate 11 may include a gate insulation layer 16, a buried word line 17, and a gate capping layer 18. More specifically, the buried word line structure may include a first trench (T1) formed in the substrate 11, a gate insulation layer 16 formed on the bottom and side surfaces of the first trench (T1), a buried word line 17 that is formed on the gate insulation layer 16 and fills at least a portion of the first trench (T1), and a gate capping layer 18 formed on the buried word line 17.

Forming the buried word line structure may include forming a first trench (T1) in the substrate 11. The first trench (T1) may have a line shape crossing the active region 13 and the impurity region 14. The first trench (T1) may be formed through an etching process after forming an etching mask on the substrate.

A hard mask layer 15A may be formed as an etch barrier for forming the first trench (T1), and the hard mask layer 15A may be patterned by the etching mask to form the first trench (T1).

For example, the hard mask layer 15A may include silicon oxide or TEOS (Tetra-Ethyl-Ortho-Silicate).

In order to define the active region 13, the device isolation layer 12 may be formed, and the impurity region 14 may be formed in at least a portion of the active region 13.

The impurity region 14 may be formed after the buried word line structure is formed. The impurity region 14 may be formed through the etching process after performing ion implantation and a doping process in the active region 13.

A plurality of impurity regions 14 may be doped with impurities of the same conductivity type. The impurity regions 14 may later become source/drain regions of the cell transistor. The impurity regions 14 may be respectively disposed on different active regions 13, and may be spaced apart from each other by a first trench (T1).

A gate insulation layer 16 may be formed on the bottom and side surfaces of the first trench (T1). The gate insulation layer 16 may be formed after surface damage caused by the etching of the first trench (T1) is healed.

The gate insulation layer 16 may be formed by oxidizing the bottom and side surfaces of the first trench (T1). In another embodiment, the gate insulation layer 16 may be formed through deposition such as chemical vapor deposition (CVD) or atomic layer deposition (ALD).

For example, the gate insulation layer 16 may include a high-K material, an oxide, a nitride, or a combination thereof.

The high-K material may include hafnium oxide, hafnium silicon oxide, hafnium silicon oxynitride, or a combination thereof. In another embodiment, the high-K material may include lanthanum oxide, lanthanum aluminum oxide, zirconium oxide, zirconium silicon oxide, zirconium silicon oxynitride, aluminum oxide, or a combination thereof.

A buried word line 17 may be formed on the gate insulation layer 16. The buried word line 17 may be formed by forming a conductive layer that fills the first trench (T1) and then performing a recessing process.

For example, the recessing process may include both an etchback process and a Chemical Mechanical Polishing (CMP) process. For example, in some embodiments, during the recessing process, a CMP process may be performed after a first etchback process, and then a second etchback process may be performed. The etchback process may be repeated after the CMP process.

The buried word line 17 may be shaped to fill at least a portion of the first trench (T1). The buried word line 17 may include a metal, a metal nitride, or a combination thereof. For example, the buried word line 17 may include molybdenum (Mo), tungsten (W), or titanium nitride (TiN). In some embodiments, the buried word line 17 may include a stacked structure of layers including materials arbitrarily selected from among molybdenum (Mo), tungsten (W), and/or titanium nitride (TiN).

After the buried word line 17 is formed, a gate capping layer 18 may be formed on the buried word line 17. The gate capping layer 18 may include an insulation material, and may be a region that fills an area of the first trench (T1) where the buried word line 17 is not formed.

The gate capping layer 18 may include, for example, silicon nitride, silicon oxide, or may include a stacked structure of silicon nitride and silicon oxide.

The surface of the gate capping layer 18 may be at the same height as the hard mask layer 15A, and the height of the gate capping layer 18 and the height of the hard mask layer 15A may be the same through the CMP process.

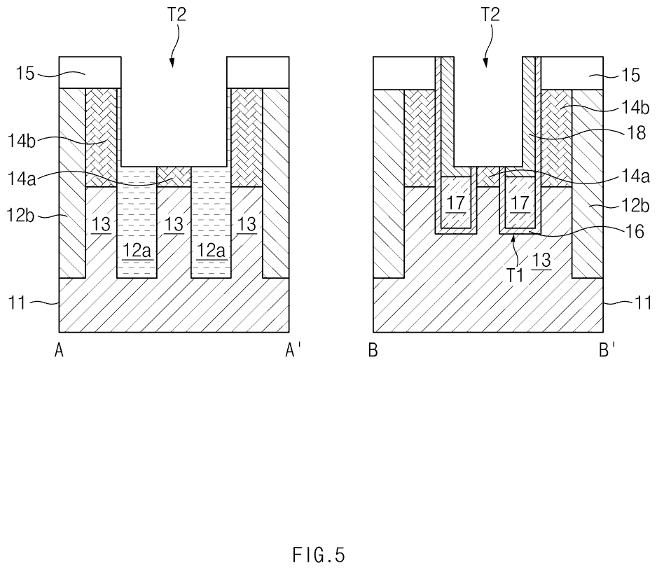

As shown in FIG. 5, a contact hole (T2) may be formed in the substrate 11. The contact hole (T2) may be a region where the conductive-line contact plug 19 is formed. The contact hole (T2) may occupy a region between two adjacent second impurity regions 14b. The contact hole (T2) may be formed by etching the hard mask layer 15A. The contact hole (T2) may have a circular or oval shape on a plane. After the contact hole (T2) is formed, a portion of the hard mask layer 15 may remain.

A portion of the substrate 11 may be etched by the contact hole (T2), and a portion of the active region 13 may be exposed. In the etching process for forming the contact hole (T2), at least a portion of the first impurity region 14a, a portion of the device isolation layer 12, and a portion of the gate capping layer 18 may be removed. More specifically, the first impurity region 14a may be recessed and exposed to a preset depth by the contact hole (T2).

As the contact hole (T2) is formed, a device isolation layer 12a in which some areas are etched and a device isolation layer 12b in which some areas are not etched may be distinguished from each other. More specifically, device isolation layers 12a in which some areas are etched may be arranged on both sides of the first impurity region 14a.

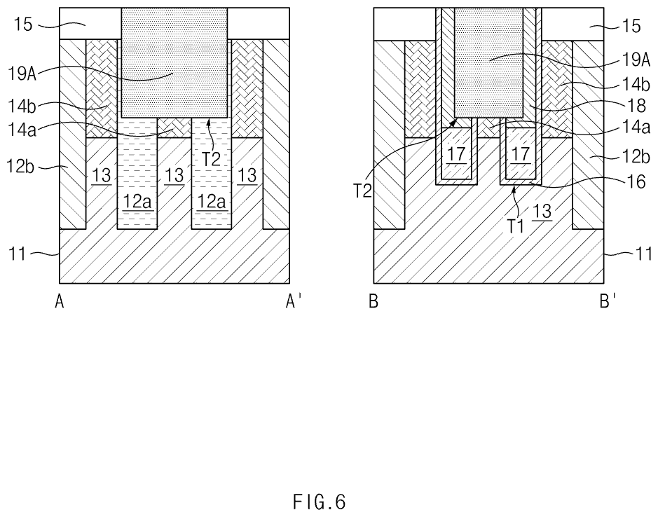

As illustrated in FIG. 6, a pre-contact plug 19A may be formed in the contact hole (T2). The pre-contact plug 19A may be formed to fill the inside of the contact hole (T2).

The pre-contact plug 19A may be formed through a deposition process or selective epitaxial growth. The pre-contact plug 19A may include at least one of polysilicon and single crystal silicon.

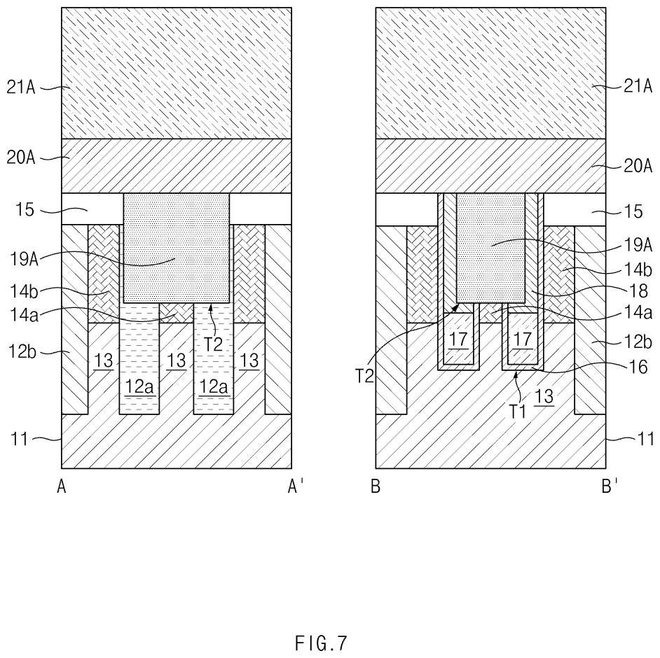

As illustrated in FIG. 7, a conductive-line conductive layer 20A and a conductive-line hard mask layer 21A may be formed sequentially on the pre-contact plug 19A and the remaining hard mask layer 15.

The conductive-line conductive layer 20A may include a metal material. For example, the conductive-line conductive layer 20A may include tungsten. According to another embodiment, the conductive-line conductive layer 20A may include a stacked structure of a metal and a metal nitride. For example, the conductive-line conductive layer 20A may include a stacked structure of tungsten and titanium nitride. The titanium nitride may operate as a barrier metal between the pre-contact plug 19A and the tungsten layer.

The conductive-line hard mask layer 21A may include an insulation material having etch selectivity for the conductive-line conductive layer 20A and the pre-contact plug 19A. For example, the conductive-line hard mask layer 21A may include silicon nitride.

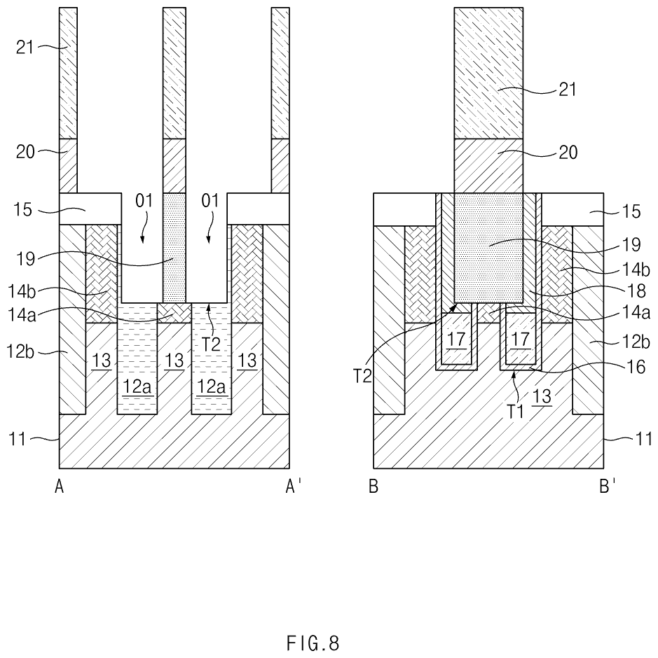

As illustrated in FIG. 8, the conductive line 20 and the conductive-line hard mask 21 may be formed by etching the conductive-line hard mask layer 21A and the conductive-line conductive layer 20A. In addition, a conductive-line contact plug 19 may be formed by etching the pre-contact plug 19A with the same width as the conductive line 20.

As the conductive-line contact plug 19 is formed to have the same width as the conductive line 20 through the etching process, a first opening portion (O1) may be formed at both sides of the conductive-line contact plug 19. The first opening portion (O1) may be a gap that is filled with a gap-fill spacer 23.

The conductive-line contact plug 19, the conductive line 20, and the conductive-line hard mask 21 may be referred to collectively as a conductive line structure. The conductive line structure may have a shape extending in the second direction (D2) shown in FIG. 1.

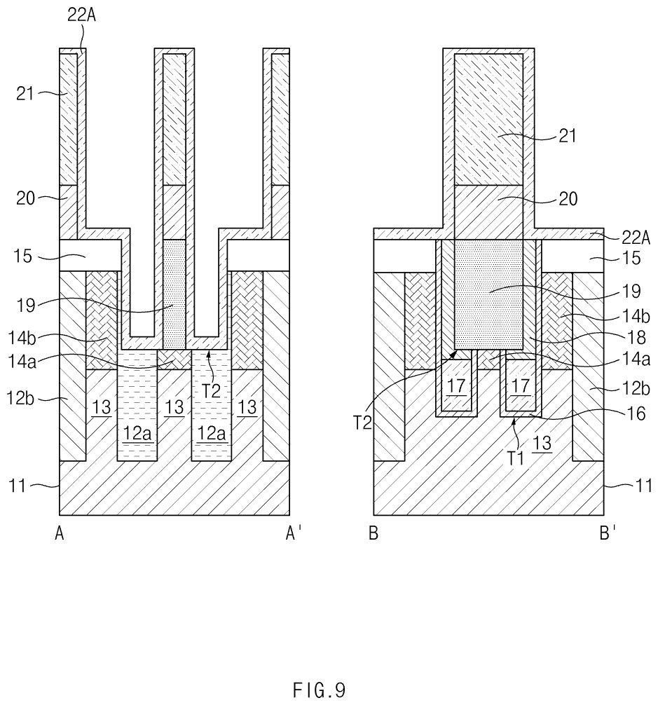

As illustrated in FIG. 9, a first spacer layer 22A may be formed on both sidewalls of the conductive-line contact plug 19, also on the bottom and side surfaces of the second trench (T1) in which the opening portion (O1) is formed, and also on the sidewalls of each of the hard mask layer 15, the conductive line 20, and the conductive-line hard mask 21.

The first spacer layer 22A may also be formed on the conductive-line hard mask 21.

The first spacer layer 22A may include a low-K material, and may include a material having a lower permittivity (lower-K) than silicon oxide or silicon nitride. For example, the first spacer layer 22A may include SiCO, which is a carbon-containing silicon-based material.

The first spacer layer 22A may be formed by atomic layer deposition (ALD), chemical vapor deposition (CVD), or cyclic chemical vapor deposition (Cyclic CVD). For example, a deposition cycle based on silicon source gas, carbon source gas, and oxygen source gas may be performed to form the first spacer layer 22A including SiCO.

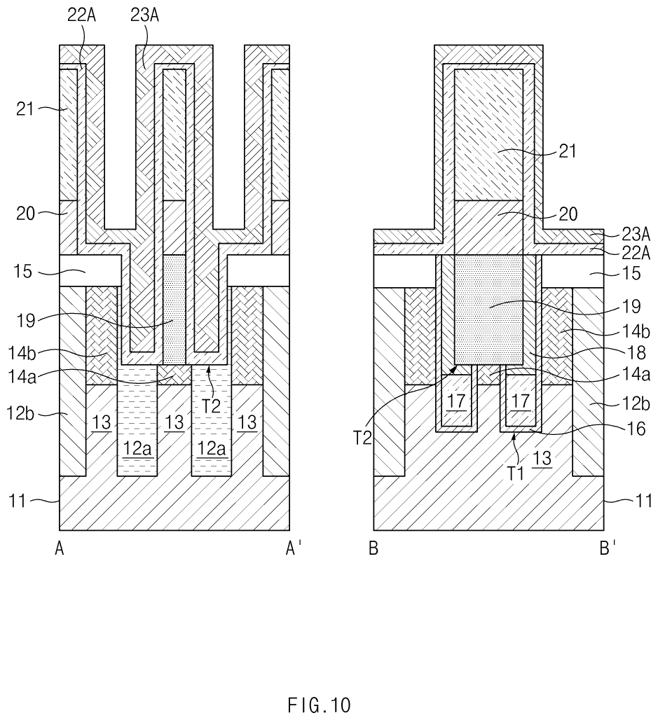

As illustrated in FIG. 10, a gap-fill spacer layer 23A may be formed on the first spacer layer 22A. The gap-fill spacer layer 23A may include a material having a higher permittivity (higher-K) than the first spacer layer 22A. For example, the gap-fill spacer layer 23A may include silicon nitride.

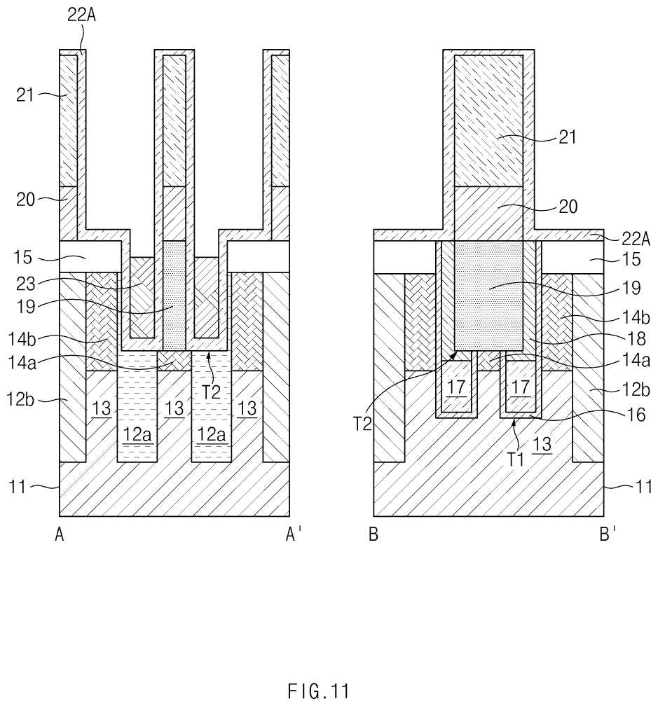

As illustrated in FIG. 11, a gap-fill spacer 23 may be formed by recessing the gap-fill spacer layer 23A. The gap-fill spacer 23 may be formed by etching back the deposited silicon nitride. The first opening portion (O1) may be filled by the gap-fill spacer 23.

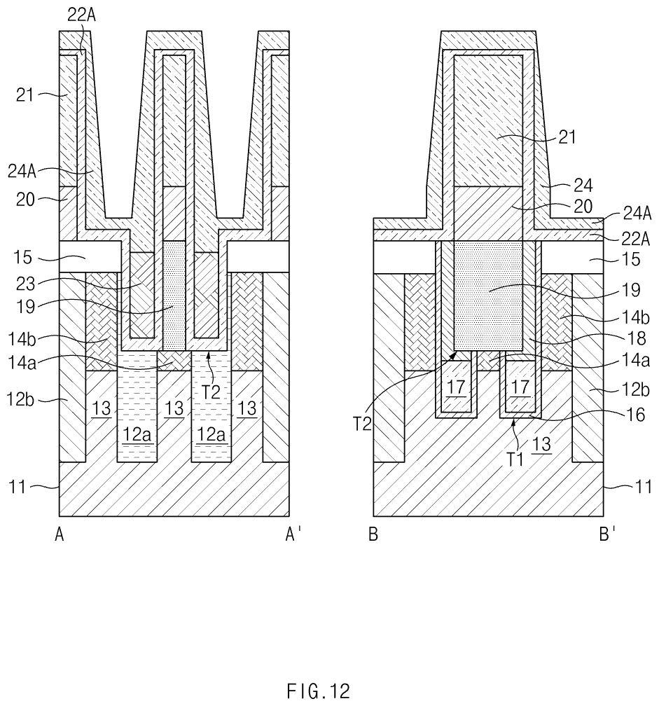

As illustrated in FIG. 12, after the gap-fill spacer 23 is formed, a second spacer layer 24A may be formed over the gap-fill spacer 23 and the first spacer layer 22A.

The second spacer layer 24A may be referred to as a tapered spacer layer, and the width of a lower portion of the second spacer layer 24A may be wider than the width of an upper portion of the second spacer layer 24A.

The second spacer layer 24A may be formed along both sidewalls of the conductive line structure, and may be formed to directly contact the top surface of the gap fill spacer 23 and the surface of the first spacer layer 22A.

For example, the second spacer layer 24A may include silicon oxide. Depending on the semiconductor fabrication process, the second spacer layer 24A may include silicon oxide doped with nitrogen, silicon oxide doped with fluorine, or silicon oxide doped with nitrogen and fluorine.

The second spacer layer 24A may be formed through an atomic layer deposition (ALD) process, and a deposition cycle based on silicon source gas and oxygen source gas may be performed.

More specifically, the second spacer layer 24A may include a deposition inhibition step during the atomic layer deposition (ALD) process. The deposition inhibition step may be a step for selectively depositing the applied reactant.

After implantation of the reactant, if a deposition inhibition material (e.g., NF3, N2, NH3, F2, etc.) is used in the deposition inhibition step, the reactant may be prevented from being deposited on the upper portion of the pattern.

When the deposition inhibition material is applied to the upper portion of the pattern, subsequent reactant materials may be prevented from being deposited within the pattern. By performing the deposition inhibition step for a plurality of cycles, a tapered insulation layer may be formed such that the reactant material is thinly deposited on the upper portion of the tapered insulation layer and is thickly deposited at the lower portion of the tapered insulation layer.

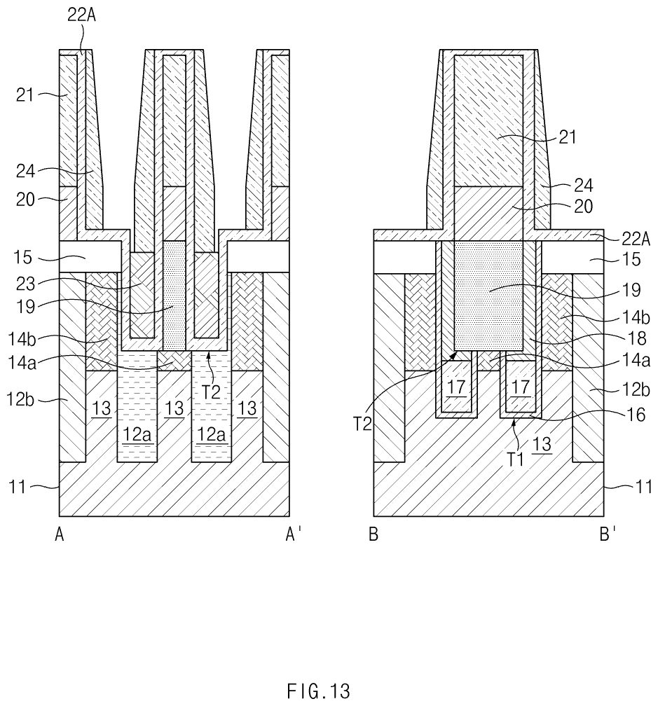

As illustrated in FIG. 13, a part of the second spacer layer 24A may be etched to form the second spacer 24.

The second spacer layer 24A may have etch selectivity with respect to the first spacer layer 22A, and the second spacer 24 may be formed through the etchback process.

The second spacer 24 may have a tapered shape in which the width of the upper portion of the second spacer 24 is narrower than the width of the lower portion of the second spacer 24.

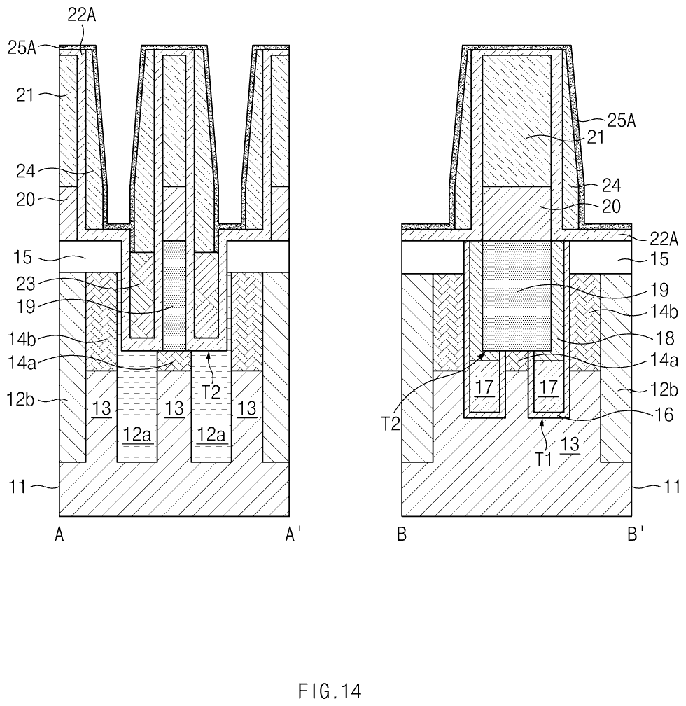

As illustrated in FIG. 14, a third spacer layer 25A may be formed on the second spacer 24. The third spacer layer 25A may be formed conformally on the second spacer 24, The third spacer layer 25A may include a low-K material having a lower permittivity (lower-K) than silicon nitride, or may include silicon nitride. For example, the third spacer layer 25A may be formed through atomic layer deposition (ALD).

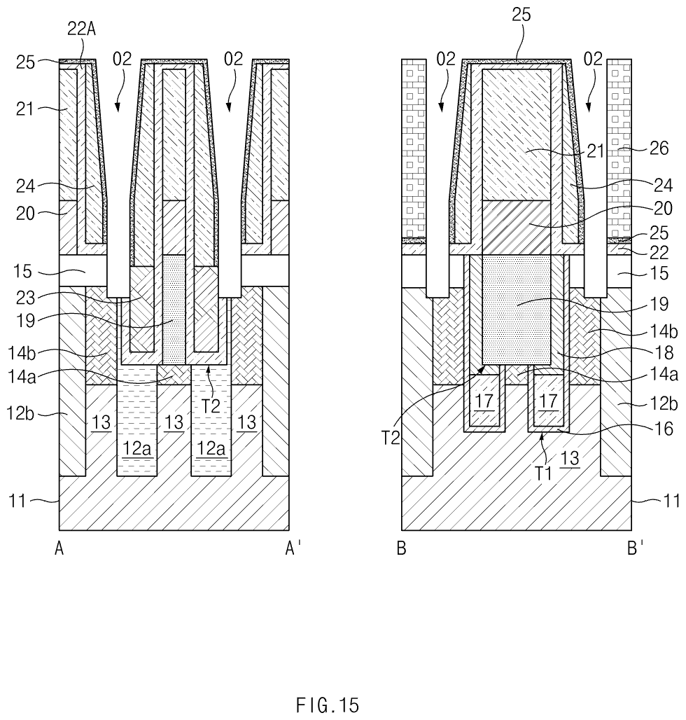

As illustrated in FIG. 15, second opening portions (O2) may be formed. Forming the second opening portions (O2) may include etching at least a portion of the third spacer layer 25A, a portion of the hard mask layer 15, a portion of the first spacer layer 22A, a portion of the second impurity region 14b, and a portion of the device isolation layer 12a.

Each of the second opening portions (O2) may be disposed between adjacent conductive line structures, and may be disposed between the third spacers 25.

Forming the second spacer 24 to have a tapered shape, allows to readily secure the area of the upper opening for the etching process. In addition, the opening defect of the bottom portion of the second spacer 24 may be resolved.

A plug isolation layer 26 may be formed on the third spacer 25. The plug isolation layer 26 may be separated by the second opening portion (O2). The plug isolation layer 26 may include silicon nitride.

As the second opening portion (O2) is formed, at least a portion of the second impurity region 14b may be exposed, and a portion of the gap-fill spacer 23 may be exposed. A portion of the exposed second impurity region 14b may be connected to the conductive pattern 27.

Anisotropic etching and isotropic etching processes may be utilized to form the second opening portion (O2).

As the second opening portion (O2) is formed, the first spacer 22, the second spacer 24, and the third spacer 25 may be defined. In some embodiments, the first spacer 22, the second spacer 24 and the third spacer 25 may be included in the spacer structure.

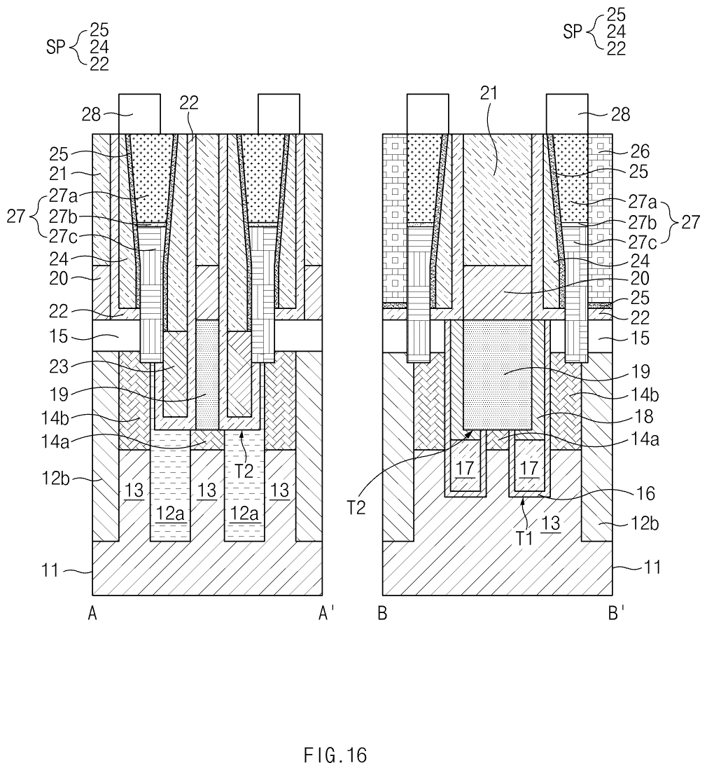

Referring to FIG. 16, a conductive pattern 27 may be formed within the second opening portion (O2).

The conductive pattern 27 may contact the second impurity region 14b, and may be arranged adjacent to the conductive line structure.

The conductive pattern 27 and the plug isolation layer 26 may be alternately arranged in a direction parallel to the direction (D2) in which the conductive line 20 extends. The conductive patterns 27 adjacent to each other may be isolated from each other by the plug isolation layer 26.

The conductive pattern 27 may include an upper plug 27a, an ohmic contact layer 27b, and a lower plug 27c.

The lower plug 27c may include a conductive material such as polysilicon.

The lower plug 27c may be formed by depositing polysilicon and then performing planarization and etchback processes.

The ohmic contact layer 27b may include, for example, metal silicide. The ohmic contact layer 27b may be formed by annealing after depositing the metal silicide. Silicidation may occur at the interface where the lower plug 27c and the ohmic contact layer 27b contact each other.

The upper plug 27a may include, for example, a conductive material such as a metal material. The upper plug 27a may be formed through gap-fill and planarization processes of the metal material. The upper plug 27a may include, for example, tungsten.

The spacer structure (SP) disposed between the conductive line 20 and the conductive pattern 27 may have a KOK (Low-K-Oxide-Low-K) stack structure or a KON (Low-K-Oxide-Nitride) stack structure.

Since the spacer structure (SP) includes a low-K material, parasitic capacitance of the conductive line 20 may be reduced. In addition, since the spacer structure (SP) has a tapered shape, a gap (spacing) between the conductive line 20 and the conductive pattern 27 can be secured, thereby reducing the parasitic capacitance.

As described above, the semiconductor device and its manufacturing method according to some embodiments of the present disclosure form tapered spacers between the conductive lines and the conductive patterns for facilitating the formation of the conductive patterns.

According to the embodiments of the present disclosure, the first spacer directly contacting sidewalls of the conductive line does not include nitride, thereby preventing nitridation of the conductive line.

In addition, according to the embodiments of the present disclosure, the first spacer includes a low-permittivity (low-K) material, and a second spacer including a tapered silicon oxide layer is formed on the first spacer, thereby improving parasitic capacitance between the conductive line and the conductive pattern.

The embodiments of the present disclosure may provide a variety of advantageous effects capable of being directly or indirectly recognized.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure. Furthermore, the embodiments may be combined to form additional embodiments.

What is claimed is:

1. A semiconductor device comprising:
a conductive-line contact plug and a conductive pattern spaced apart from each other in a first direction;
a conductive line disposed over the conductive-line contact plug and extending in a second direction perpendicular to the first direction; and
a spacer structure configured to contact sidewalls of the conductive line and the conductive-line contact plug, and configured such that a width of an upper portion of the spacer structure is narrower than a width of a lower portion of the spacer structure.

2. The semiconductor device according to claim 1, wherein the spacer structure includes:
a first spacer configured to contact the sidewalls of the conductive line and the conductive-line contact plug;
a second spacer configured to contact the first spacer, and configured such that a width of an upper portion of the second spacer is narrower than a width of a lower portion of the second spacer; and
a third spacer disposed between the second spacer and the conductive pattern.

3. The semiconductor device according to claim 2, wherein the first spacer includes:
a material having a lower permittivity (lower-K) than silicon nitride.

4. The semiconductor device according to claim 2, wherein the first spacer includes silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof.

5. The semiconductor device according to claim 2, wherein the second spacer includes silicon oxide.

6. The semiconductor device according to claim 5, wherein the silicon oxide is doped with one of nitrogen or fluorine.

7. The semiconductor device according to claim 2, wherein the third spacer includes silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof.

8. The semiconductor device according to claim 1, wherein the conductive pattern is configured such that a width of a lower portion of the conductive pattern is narrower than a width of an upper portion of the conductive pattern.

9. The semiconductor device according to claim 1, further comprising:
a memory element disposed on the conductive pattern.

10. The semiconductor device according to claim 1, wherein the conductive pattern includes:
a lower plug including polysilicon;
an ohmic contact layer disposed on the lower plug and including metal silicide; and
an upper plug disposed on the ohmic contact layer and including a metal material.

11. The semiconductor device according to claim 1, further comprising:
a first impurity region and a second impurity region that are formed in a substrate,
wherein the conductive-line contact plug is connected to the first impurity region.

12. The semiconductor device according to claim 11, wherein the conductive pattern is connected to the second impurity region.

13. The semiconductor device according to claim 11, wherein the first impurity region is disposed between two adjacent buried word lines.

14. The semiconductor device according to claim 1, wherein:
the conductive line is a bit line; and
the conductive pattern is a storage-node contact plug.

15. A semiconductor device comprising:
a plurality of conductive lines spaced apart from each other on a substrate;
a plurality of conductive-line contact plugs disposed below the conductive lines, respectively;
a plurality of conductive patterns disposed between the conductive lines; and
a plurality of spacer structures disposed between the conductive patterns and the conductive lines,
wherein each of the spacer structures includes:
a first spacer configured to contact sidewalls of the conductive line and the conductive-line contact plug;
a second spacer configured to contact the first spacer and configured such that a width of an upper portion of the second spacer is narrower than a width of a lower portion of the second spacer; and
a third spacer disposed between the second spacer and the conductive patterns.

16. The semiconductor device according to claim 15, further comprising:
a plug isolation layer disposed between the conductive patterns,
wherein the conductive patterns and the plug isolation layer are alternately arranged in a direction in which the conductive lines extend.

17. The semiconductor device according to claim 16, wherein the plug isolation layer includes an insulation material.

18. The semiconductor device according to claim 15, wherein the first spacer includes:
a material having a lower permittivity (lower-K) than silicon nitride.

19. The semiconductor device according to claim 15, wherein the first spacer includes silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof

20. The semiconductor device according to claim 15, wherein the second spacer includes silicon oxide.

21. The semiconductor device according to claim 20, wherein the silicon oxide is doped with one of nitrogen or fluorine.

22. The semiconductor device according to claim 15, wherein the third spacer includes silicon carbide (SiC), silicon oxycarbide (SiCO), silicon carbon nitride (SiCN), silicon oxycarbonitride (SiOCN), silicon boron nitride (SiBN), silicon boron-carbon-nitride (SiBCN), boron nitride (BN), or a combination thereof.
